(19) United States
(12) Patent Application Publication
(10) Pub. No.: US 2025/0309615 A1
(43) Pub. Date: Oct. 2, 2025

(54) SURFACE EMITTING SEMICONDUCTOR LASER AND OPTICAL TRANSMISSION APPARATUS

(71) Applicant: FUJIFILM Business Innovation Corp., Tokyo (JP)

(72) Inventors: Koga MIZUNO, Kanagawa (JP); Takeshi MINAMIRU, Kanagawa (JP); Yuto IWANE, Kanagawa (JP); Tsutomu HAMADA, Kanagawa (JP); Kazutaka TAKEDA, Kanagawa (JP); Hideki FUKUNAGA, Kanagawa (JP); Akemi MURAKAMI, Kanagawa (JP); Hideo NAKAYAMA, Kanagawa (JP)

(73) Assignee: FUJIFILM Business innovation Corp., Tokyo (JP)

(21) Appl. No.: 18/795,426

(22) Filed: Aug. 6, 2024

(30) Foreign Application Priority Data
Mar. 27, 2024 (JP) 2024-052304

(51) Int. Cl. H01S 5/183

(52) U.S. Cl. CPC H01S 5/18391; H01S 5/18369

(57) ABSTRACT

A surface emitting semiconductor laser includes: a substrate; a first semiconductor multilayer film reflective mirror stacked on the substrate; an active layer stacked on the first semiconductor multilayer film reflective mirror; a second semiconductor multilayer film reflective mirror that includes a current confinement layer and is stacked on the active layer; a dielectric multilayer film reflective mirror stacked on the second semiconductor multilayer film reflective mirror; and a metal layer that is disposed between the second semiconductor multilayer film reflective mirror and the dielectric multilayer film reflective mirror, has an opening in which an aperture representing a portion that is not subjected to oxidation confinement in the current confinement layer is disposed inside as viewed from a stacking direction, and has a center of the opening at a position shifted from a center of the aperture.

### CROSS-REFERENCE TO RELATED APPLICATIONS

This application is based on and claims priority under 35 USC 119 from Japanese Patent Application No. 2024-052304 filed Mar. 27, 2024.

### BACKGROUND

### (i) Technical Field

The present disclosure relates to a surface emitting semiconductor laser and an optical transmission apparatus.

### (ii) Related Art

JP2022-2299A discloses a surface emitting laser including a vertical cavity surface emitting laser (VCSEL) structure having an aperture due to a current narrowing structure, an aperture in an upper distributed Bragg reflector (DBR) of the VCSEL structure, and an optical discontinuous member formed in a spaced region.

JP2010-135854A discloses a surface emitting semiconductor laser including a semiconductor layer that includes an active layer and a current confinement layer, and a lateral mode adjustment portion that is formed on the semiconductor layer, in which the current confinement layer has a current injection region and a current confinement region, the lateral mode adjustment portion has a high reflection region and a low reflection region, the high reflection region is formed in a region including a first facing region with respect to a center point of the current injection region and has a cross shape, and the low reflection region is formed in an unformed region of the high reflection region in a facing region with respect to the current injection region.

### SUMMARY

Aspects of non-limiting embodiments of the present disclosure relate to a surface emitting semiconductor laser and an optical transmission apparatus that expand a modulation band of light in a configuration in which a metal layer is disposed between a second semiconductor multilayer film reflective mirror having a current confinement layer and a dielectric multilayer film reflective mirror, as compared to a configuration in which a shape of an opening of the metal layer is the same as a shape of an aperture of the current confinement layer and centers of the opening and the aperture coincide with each other as viewed from a stacking direction.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a surface emitting semiconductor laser including: a substrate; a first semiconductor multilayer film reflective mirror stacked on the substrate; an active layer stacked on the first semiconductor multilayer film reflective mirror; a second semiconductor multilayer film reflective mirror that includes a current confinement layer and is stacked on the active layer; a dielectric multilayer film reflective mirror stacked on the second semiconductor multilayer film reflective mirror; and a metal layer that is disposed between the second semiconductor multilayer film reflective mirror and the dielectric multilayer film reflective mirror, has an opening in which an aperture representing a portion that is not subjected to oxidation confinement in the current confinement layer is disposed inside as viewed from a stacking direction, and has a center of the opening at a position shifted from a center of the aperture.

### BRIEF DESCRIPTION OF THE DRAWINGS

Exemplary embodiment(s) of the present invention will be described in detail based on the following figures, wherein:

FIG. 1 is a cross-sectional view showing a surface emitting semiconductor laser according to a first exemplary embodiment of the present disclosure;

FIG. 2 is an enlarged cross-sectional view around an active layer of the surface emitting semiconductor laser shown in FIG. 1;

FIG. 3 is a plan view of an opening and an aperture of a metal layer as viewed from a stacking direction;

FIG. 4 is a plan view of the opening, the aperture, and a recess portion of the metal layer as viewed from the stacking direction;

FIG. 5 is a view schematically showing the surface emitting semiconductor laser shown in FIG. 1;

FIG. 6 is a plan view of an opening and an aperture of a metal layer of a surface emitting semiconductor laser according to a second exemplary embodiment of the present disclosure as viewed from a stacking direction;

FIG. 7 is a plan view of an opening and an aperture of a metal layer of a surface emitting semiconductor laser according to another exemplary embodiment of the present disclosure as viewed from a stacking direction;

FIG. 8 is a plan view of an opening and an aperture of a metal layer of a surface emitting semiconductor laser according to still another exemplary embodiment of the present disclosure as viewed from a stacking direction;

FIG. 9 is a plan view of an opening and an aperture of a metal layer of a surface emitting semiconductor laser according to still yet another exemplary embodiment of the present disclosure as viewed from a stacking direction;

FIG. 10 is a plan view of an opening and an aperture of a metal layer of a surface emitting semiconductor laser according to still yet another exemplary embodiment of the present disclosure as viewed from a stacking direction;

FIG. 11 is a plan view of an opening and an aperture of a metal layer of a surface emitting semiconductor laser according to still yet another exemplary embodiment of the present disclosure as viewed from a stacking direction;

FIG. 12 is a plan view of an opening and an aperture of a metal layer of a surface emitting semiconductor laser according to still yet another exemplary embodiment of the present disclosure as viewed from a stacking direction;

FIG. 13 is a plan view of an opening and an aperture of a metal layer of a surface emitting semiconductor laser according to still yet another exemplary embodiment of the present disclosure as viewed from a stacking direction;

FIG. 14 is a plan view of an opening and an aperture of a metal layer of a surface emitting semiconductor laser according to still yet another exemplary embodiment of the present disclosure as viewed from a stacking direction;

FIG. 15 is a plan view of an opening and an aperture of a metal layer of a surface emitting semiconductor laser according to still yet another exemplary embodiment of the present disclosure as viewed from a stacking direction;

FIG. 16 is a plan view of an opening and an aperture of a metal layer of a surface emitting semiconductor laser according to still yet another exemplary embodiment of the present disclosure as viewed from a stacking direction;

FIG. 17 is a plan view of an opening and an aperture of a metal layer of a surface emitting semiconductor laser according to still yet another exemplary embodiment of the present disclosure as viewed from a stacking direction;

FIG. 18 is a plan view of an opening and an aperture of a metal layer of a surface emitting semiconductor laser according to still yet another exemplary embodiment of the present disclosure as viewed from a stacking direction;

FIG. 19 is a plan view of an opening and an aperture of a metal layer of a surface emitting semiconductor laser according to still yet another exemplary embodiment of the present disclosure as viewed from a stacking direction;

FIG. 20 is a plan view of an opening and an aperture of a metal layer of a surface emitting semiconductor laser according to still yet another exemplary embodiment of the present disclosure as viewed from a stacking direction;

FIG. 21 is a plan view of an opening and an aperture of a metal layer of a surface emitting semiconductor laser according to still yet another exemplary embodiment of the present disclosure as viewed from a stacking direction;

FIG. 22 is a plan view of an opening and an aperture of a metal layer of a surface emitting semiconductor laser according to still yet another exemplary embodiment of the present disclosure as viewed from a stacking direction; and

FIG. 23 is a plan view of an opening and an aperture of a metal layer of a surface emitting semiconductor laser according to still yet another exemplary embodiment of the present disclosure as viewed from a stacking direction.

### DETAILED DESCRIPTION

Hereinafter, exemplary embodiments for carrying out the technique of the present disclosure will be described in detail with reference to the drawings. Components and processing having identical operations, actions, and functions are designated by identical reference signs throughout the drawings, and redundant descriptions may be omitted as appropriate. Each drawing is merely schematically shown to the extent that the technology of the present disclosure can be fully understood. Thus, the technique of the present disclosure is not limited to only the shown examples. In addition, in the present exemplary embodiment, descriptions of configurations that are not directly related to the technology of the present disclosure and of well-known configurations may be omitted.

### First Exemplary Embodiment

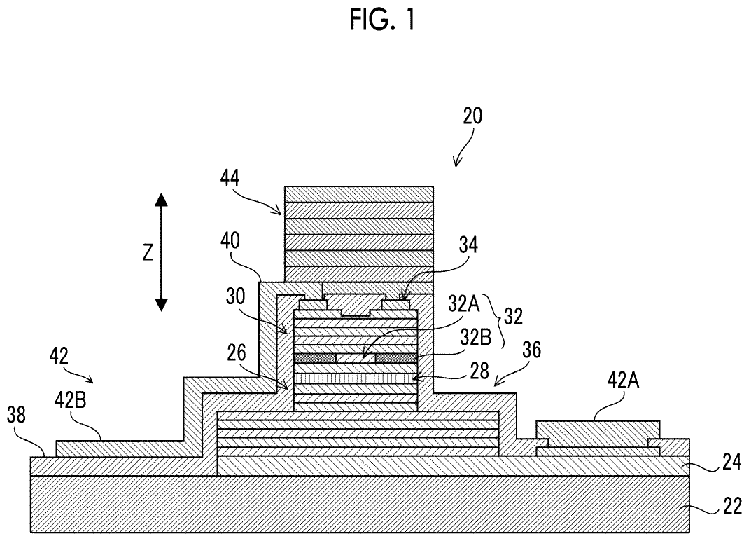

FIG. 1 is a cross-sectional view showing a surface emitting semiconductor laser 20 according to a first exemplary embodiment of the present disclosure.

As shown in FIG. 1, the surface emitting semiconductor laser 20 according to the present exemplary embodiment is, for example, a vertical cavity surface emitting laser (VCSEL).

As shown in FIG. 1, the surface emitting semiconductor laser 20 according to the present exemplary embodiment includes a substrate 22, a contact layer 24, a first semiconductor multilayer film reflective mirror 26, an active layer 28, a second semiconductor multilayer film reflective mirror 30, a contact metal 34, and a dielectric multilayer film reflective mirror 44.

In the present exemplary embodiment, the first semiconductor multilayer film reflective mirror 26 is an n-type, and the second semiconductor multilayer film reflective mirror 30 is a p-type. The present disclosure is not limited to this configuration.

In the surface emitting semiconductor laser 20 according to the present exemplary embodiment, each configuration including the contact layer 24, the first semiconductor multilayer film reflective mirror 26, the active layer 28, the second semiconductor multilayer film reflective mirror 30, and the dielectric multilayer film reflective mirror 44 forms a mesa structural body 36. The mesa structural body 36 constitutes a laser portion of the surface emitting semiconductor laser 20.

The substrate 22 is, for example, a semi-insulating gallium arsenide (GaAs) substrate. The semi-insulating GaAs substrate is a GaAs substrate in which impurities are not doped. The semi-insulating GaAs substrate has a very high resistivity, and, for example, a sheet resistance value of the substrate shows a value of approximately several MQ.

A material of the substrate 22 may be a material other than GaAs, and for example, gallium nitride (GaN) or indium phosphide (InP) may be used.

The contact layer 24 is stacked on the substrate 22. The contact layer 24 is formed of, for example, an n-type GaAs layer doped with Si.

The contact layer 24 is connected to the n-type first semiconductor multilayer film reflective mirror 26. An electrode pad 42B on an n side is formed at the contact layer 24 Therefore, the contact layer 24 has a function of applying a negative potential to the laser portion configured by the mesa structural body 36.

The contact layer 24 may double as a buffer layer that is provided to achieve favorable crystallinity of the substrate surface after thermal cleaning, for example.

The n-type first semiconductor multilayer film reflective mirror 26 is stacked on the contact layer 24. The first semiconductor multilayer film reflective mirror 26 constitutes a lower distributed Bragg reflector (DBR).

The first semiconductor multilayer film reflective mirror 26 is a multilayer film reflective mirror configured by alternately and repeatedly stacking two semiconductor films having different refractive indexes from each other. Specifically, the first semiconductor multilayer film reflective mirror 26 is configured by alternately and repeatedly stacking a low refractive index film of the n-type based on Al_{0.90}GaAs and a high refractive index film of the n-type based on Al_{0.15}GaAs. A refractive index of n-type Al_{0.90}GaAs is lower than a refractive index of n-type Al_{0.15}GaAs.

The active layer 28 is stacked on the first semiconductor multilayer film reflective mirror 26. The active layer 28 functions as a resonator. The details of the active layer 28 will be described later.

The p-type second semiconductor multilayer film reflective mirror 30 is stacked on the active layer 28. In other words, the second semiconductor multilayer film reflective mirror 30 is stacked on the first semiconductor multilayer film reflective mirror 26 with the active layer 28 interposed between the second semiconductor multilayer film reflective mirror 30 and the first semiconductor multilayer film reflective mirror 26. The second semiconductor multilayer film reflective mirror 30 constitutes an upper DBR.

The second semiconductor multilayer film reflective mirror 30 is a multilayer film reflective mirror configured by alternately and repeatedly stacking two semiconductor films having different refractive indexes from each other. Specifically, the second semiconductor multilayer film reflective mirror 30 is configured by alternately and repeatedly stacking a low refractive index film of the p-type based on Al_{0.90}GaAs and a high refractive index film of the p-type based on Al_{0.15}GaAs. A refractive index of p-type Al_{0.90}GaAs is lower than a refractive index of p-type Al_{0.15}GaAs.

In addition, the second semiconductor multilayer film reflective mirror 30 includes a selective oxidation layer 32. The selective oxidation layer 32 is an example of a current confinement layer. The selective oxidation layer 32 is disposed above the active layer 28. The selective oxidation layer 32 includes an aperture 32A representing a portion that is not subjected to oxidation confinement and an oxidation-confined region 32B that is a region subjected to oxide confinement. In addition to selective oxidation of current confinement, for example, current confinement may be performed by temporarily forming a pattern corresponding to an opening portion in stacking a layered structure to selectively make a current easily pass to the opening portion or by performing ion implantation to make the current not easily pass to a portion subjected to ion implantation.

An amount of aluminum per unit amount of an aluminum-containing material forming the selective oxidation layer 32 may be more than an amount of aluminum per unit amount of an aluminum-containing material forming the second semiconductor multilayer film reflective mirror 30. The selective oxidation layer 32 is formed of, for example, aluminum arsenide (AlAs) or Al_{0.98}GaAs.

An interlayer insulating film 38 as an inorganic insulating film is deposited around the semiconductor layer including the mesa structural body 36. The interlayer insulating film 38 is stretched from the side surface of the mesa structural body 36 to the surface of the substrate 22. In addition, the interlayer insulating film 38 is disposed below an electrode pad 42A.

The interlayer insulating film 38 is formed of, for example, a silicon nitride film (SiN film). A material of the interlayer insulating film 38 is not limited to the silicon nitride film, and, for example, a silicon oxide film (SiO₂ film) or a silicon oxynitride film (SiON film) may be used.

A wiring 40 is provided on the interlayer insulating film 38. One end side of the wiring 40 is connected to the contact metal 34 which will be described below. On the other hand, the other end side of the wiring 40 is stretched from the contact metal 34 to the surface of the substrate 22 through the side surface of the mesa structural body 36 on the interlayer insulating film 38. In addition, the electrode pad 42A on a p side is formed by a portion of the interlayer insulating film 38 located on the surface of the substrate 22.

The contact metal 34 is an example of a metal layer and is provided on the second semiconductor multilayer film reflective mirror 30. In other words, the contact metal 34 is disposed between the second semiconductor multilayer film reflective mirror 30 and the dielectric multilayer film reflective mirror 44.

In addition, the contact metal 34 is connected to the wiring 40. For example, a stacked film of Ti/Au may be used as the contact metal 34.

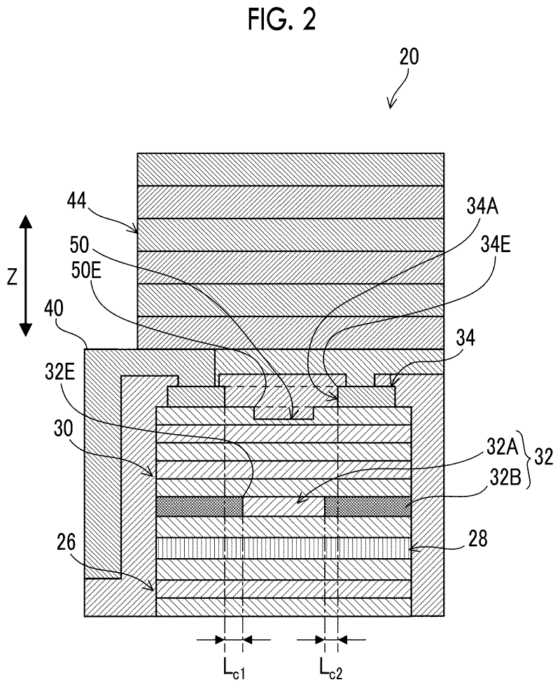

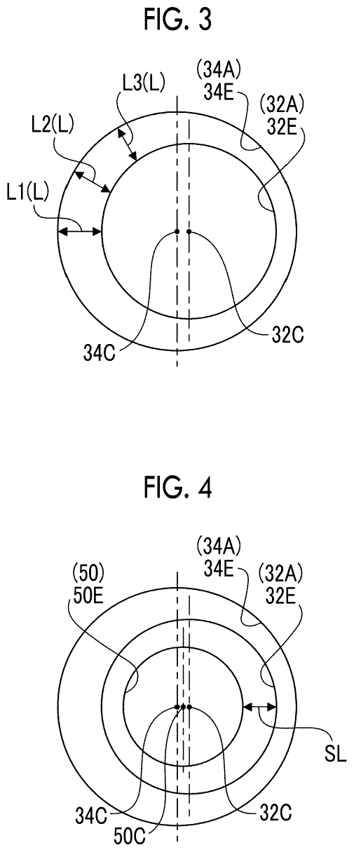

As shown in FIG. 3, the contact metal 34 has an opening 34A in which the aperture 32A is disposed inside as viewed from the stacking direction. The stacking direction referred to herein is a stacking direction of each layer (may be referred to as each reflective mirror) constituting the surface emitting semiconductor laser 20, and is a direction indicated by the arrow Z in FIGS. 1 and 2. Hereinafter, in a case where the term “stacking direction” is simply used, the term indicates a direction indicated by the arrow Z.

As shown in FIG. 3, as viewed from the stacking direction, a center 34C of the opening 34A of the contact metal 34 is located at a position shifted from a center 32C of the aperture 32A.

In addition, as viewed from the stacking direction, a portion in which a distance L between an edge 34E of the opening 34A of the contact metal 34 and an edge 32E of the aperture 32A continuously changes along the outer periphery of the aperture 32A may be provided. In other words, the shape of the opening 34A, the shape of the aperture 32A, the position of the center 34C of the opening 34A, and the position of the center 32C of the aperture 32A may be set, respectively, to have the continuously changing portion. The edge 34E of the aperture 32A referred to herein indicates a boundary between a portion that is not subjected to oxidation confinement and a region subjected to oxidation confinement in the selective oxidation layer 32. In addition, the phrase of being along the outer periphery of the aperture 32A indicates being along the boundary.

In addition, the shape of the aperture 32A may be circular or elliptical, and the shape of the opening 34A may be circular or elliptical. As viewed from the stacking direction, the shape of the opening 34A may be the same as the shape of the aperture 32A. In the present exemplary embodiment, as an example, the shapes of the aperture 32A and the opening 34A are circular.

In addition, the dielectric multilayer film reflective mirror 44 is stacked on the contact metal 34. The dielectric multilayer film reflective mirror 44 may be included in the upper DBR.

The dielectric multilayer film reflective mirror 44 is stacked on the second semiconductor multilayer film reflective mirror 30. Specifically, the dielectric multilayer film reflective mirror 44 is stacked on the contact metal 34 stacked on the second semiconductor multilayer film reflective mirror 30.

The dielectric multilayer film reflective mirror 44 is a multilayer film reflective mirror configured by alternately and repeatedly stacking two dielectric films having different refractive indexes from each other. Specifically, the dielectric multilayer film reflective mirror 44 is configured by alternately and repeatedly stacking a high refractive index film formed of tantalum pentoxide (Ta₂O₅) and a low refractive index film formed by silicon oxide film (SiO₂ film).

In addition, in the present exemplary embodiment, for example, a recess portion 50 is formed in the uppermost layer of the second semiconductor multilayer film reflective mirror 30 (see FIG. 2). As shown in FIG. 4, the recess portion 50 is disposed inside the aperture 32A as viewed from the stacking direction. In addition, a center 50C of the recess portion 50 is located at a position shifted from the center 32C of the aperture 32A. The present disclosure is not limited to this configuration, and the center 50C of the recess portion 50 may coincide with the center 32C of the aperture 32A or the center 34C of the opening 34A.

In addition, as viewed from the stacking direction, a portion in which a distance SL between an edge 50E of the recess portion 50 and the edge 32E of the aperture 32A continuously changes along the outer periphery of the aperture 32A may be provided. In other words, the shape of the recess portion 50, the shape of the aperture 32A, the position of the center 50C of the recess portion 50, and the position of the center 32C of the aperture 32A may be set, respectively, to have the continuously changing portion.

In addition, as viewed from the stacking direction, the shape of the recess portion 50 and the shape of the aperture 32A may be the same as or different from each other. In addition, the shape of the recess portion 50 may be the same as or different from the shape of the opening 34A. In the present exemplary embodiment, as an example, the shape of the recess portion 50 is circular as in the aperture 32A and the opening 34A.

Next, the operational effects of the present exemplary embodiment will be described.

In the surface emitting semiconductor laser 20 according to the present exemplary embodiment, as viewed from the stacking direction, the aperture 32A is disposed inside the opening 34A of the contact metal 34, and the center 34C of the opening 34A is located at a position shifted from the center 32C of the aperture 32A. Thus, as shown in FIG. 3, a plurality of portions (regions) in which the distance L between the edge 34E of the opening 34A and the edge 32E of the aperture 32A is different are formed. The distances L1, L2, and L3 in FIG. 3 are different distances. The distance L between the edge 34E of the opening 34A and the edge 32E of the aperture 32A corresponds to a resonator length. That is, since a plurality of portions having different distances L are formed between the edge 34E of the opening 34A and the edge 32E of the aperture 32A, a plurality of resonator lengths can be obtained. Then, an external resonator is formed in a pseudo manner for each resonator length.

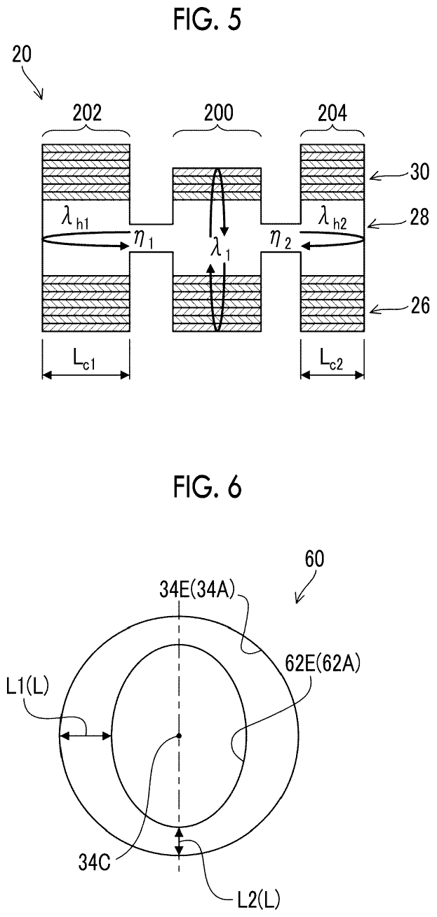

FIG. 5 schematically shows the surface emitting semiconductor laser 20. In FIG. 5, reference numerals L_{c1} and L_{c2} each indicate a resonator length. That is, the surface emitting semiconductor laser 20 includes a first external resonator 202 and a second external resonator 204 corresponding to the respective resonator lengths L_{c1} and L_{c2}. In addition, a main resonator 200 is provided in a portion between the first external resonator 202 and the second external resonator 204 in FIG. 5. Here, the first external resonator 202 and the second external resonator 204 are coupled to the main resonator 200 in a lateral direction (direction perpendicular to the stacking direction). In addition, in FIG. 5, a coupling coefficient between the main resonator 200 and the first external resonator 202 is denoted by η₁, a coupling coefficient between the main resonator 200 and the second external resonator 204 is denoted by η₂, a resonance wavelength of the main resonator 200 is denoted by λ₁, a resonance wavelength of the first external resonator 202 is denoted by λₕ₁, and a resonance wavelength of the second external resonator 204 is denoted by λₕ₂.

As shown in FIG. 3, in the surface emitting semiconductor laser 20 in the present exemplary embodiment, as viewed from the stacking direction, the aperture 32A is disposed inside the opening 34A, and the center 34C of the opening 34A is located at a position shifted from the center 32C of the aperture 32A. Thus, a plurality of resonator lengths can be obtained. That is, a plurality of the external resonators having different resonance frequencies are formed between the edge 34E of the opening 34A and the edge 32E of the aperture 32A. By forming the plurality of the external resonators in this manner, the coupling resonance effect can be obtained in any one of the plurality of external resonators even in a case where the use environment (temperature, driving current, and the like) is changed. As a result, in the surface emitting semiconductor laser 20 in the present exemplary embodiment, as compared with a configuration in which the shape of the opening 34A and the shape of the aperture 32A are the same, and the centers 34C and 32C of the opening 34A and the aperture 32A coincide with each other as viewed from the stacking direction, it is possible to expand a modulation band of light.

In the surface emitting semiconductor laser 20 in the present exemplary embodiment, as viewed from the stacking direction, in a case where the portion in which the distance L between the edge 34E of the opening 34A and the edge 32E of the aperture 32A continuously changes along the outer periphery of the aperture 32A is provided, it is possible to continuously expand the modulation band of light as compared with a case where the distance L between the edge 34E of the opening 34A and the edge 32E of the aperture 32A intermittently changes along the outer periphery of the aperture 32A. Specifically, in a case where the portion in which the distance L continuously changes is provided as shown in FIG. 3, it is possible to form a large number of continuous external resonators and to continuously expand the modulation band of light.

In the surface emitting semiconductor laser 20 in the present exemplary embodiment, as viewed from the stacking direction, in a case where the distance L between the edge 34E of the opening 34A and the edge 32E of the aperture 32A continuously changes over the entire circumference of the aperture 32A, there is no portion in which the distance L changes intermittently. Thus, it is possible to continuously expand the modulation band of light.

In the surface emitting semiconductor laser 20 in the present exemplary embodiment, in a case where the shape of the aperture 32A is circular or elliptical and the shape of the opening 34A is circular or elliptical, it is possible to continuously expand the modulation band of the light as compared with a case where the shape of each of the aperture 32A and the opening 34A is polygonal.

In the surface emitting semiconductor laser 20 in the present exemplary embodiment, as viewed from the stacking direction, in a case where the shape of the opening 34A is the same as the shape of the aperture 32A, it is possible to continuously expand the modulation band of the light as compared with a case where the shapes of the aperture 32A and the opening 34A are different from each other.

In the surface emitting semiconductor laser 20 in the present exemplary embodiment, as viewed from the stacking direction, in a case where the recess portion 50 is provided in the second semiconductor multilayer film reflective mirror 30, it is possible to increase the leakage of light to the external resonator by changing the equivalent refractive index between the recess portion 50 and the peripheral portion of the recess portion 50. As a result, the coupling coefficient of the external resonator increases. In addition, in the surface emitting semiconductor laser 20, in a case where the recess portion 50 is disposed inside the aperture 32A and the center 50C of the recess portion 50 is located at the position shifted from the center 32C of the aperture 32A, it is possible to expand the modulation band of light as compared with a case where the center 50C of the recess portion 50 and the center 32C of the aperture 32A coincide with each other as viewed from the stacking direction, in the similar manner to the relationship between the aperture 32A and the opening 34A.

In the surface emitting semiconductor laser 20 in the present exemplary embodiment, in a case where the shape of the aperture 32A is circular or elliptical and the shape of the recess portion 50 is circular or elliptical, it is possible to continuously expand the modulation band of the light as compared with a case where the shape of each of the aperture 32A and the recess portion 50 is polygonal.

In the surface emitting semiconductor laser 20 in the present exemplary embodiment, as viewed from the stacking direction, in a case where the shape of the recess portion 50 is the same as the shape of the aperture 32A, it is possible to continuously expand the modulation band of the light as compared with a case where the shapes of the aperture 32A and the recess portion 50 are different from each other.

### Second Exemplary Embodiment

Next, a surface emitting semiconductor laser 60 according to a second exemplary embodiment of the present disclosure will be described. The identical configuration to the configuration of the first exemplary embodiment will not be described.

As shown in FIG. 6, in the surface emitting semiconductor laser 60 according to the present exemplary embodiment, the shape of an opening 34A is different from the shape of an aperture 62A. Specifically, the opening 34A has a circular shape, and the aperture 62A has an elliptical shape. In addition, in the surface emitting semiconductor laser 60 in the present exemplary embodiment, as viewed from the stacking direction, the aperture 62A is disposed inside the opening 34A, and a center 34C of the opening 34A and a center of the aperture 62A coincide with each other. In FIG. 6, only the center 34C is denoted by the reference numeral, and the reference numeral of the center of the aperture 62A is omitted.

Next, the operational effects of the present exemplary embodiment will be described. The similar operational effects to the operational effects obtained in the first exemplary embodiment are appropriately omitted.

In the surface emitting semiconductor laser 60 in the present exemplary embodiment, a distance L between an edge 34E of the opening 34A and an edge 62E of the aperture 62A changes along the outer periphery of the aperture 62A. That is, in the surface emitting semiconductor laser 60, a plurality of external resonators having different resonance frequencies are formed between the edge 34E of the opening 34A and the edge 62E of the aperture 62A. Therefore, as compared with the configuration in which a single external resonator is formed between the edge 34E of the opening 34A and the edge 32E of the aperture 32A, it is possible to expand the modulation band of light.

### Other Exemplary Embodiments

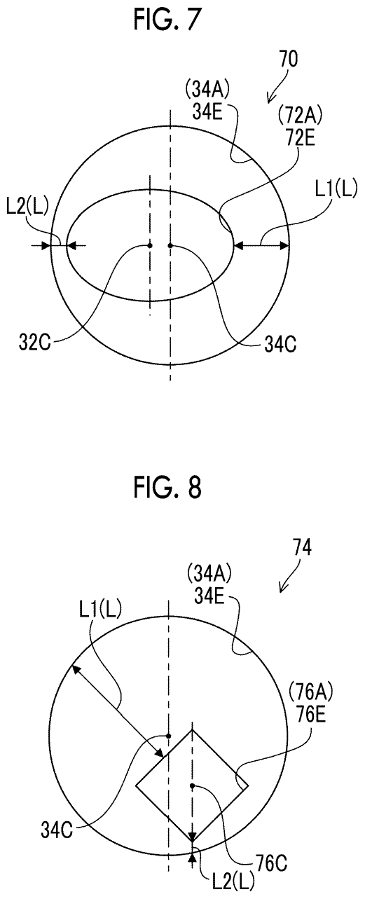

In the surface emitting semiconductor laser 20 in the first exemplary embodiment, as viewed from the stacking direction, the shape of the aperture 32A and the shape of the opening 34A are circular and the same as each other, and the center 34C of the opening 34A is located at a position shifted from the center 32C of the aperture 32A, but the present disclosure is not limited to this configuration. For example, surface emitting semiconductor lasers 70, 74, 78, 84, 86, 90, 94, 98, 102, and 106 shown in FIGS. 7 to 16 may be used. Each of the surface emitting semiconductor lasers 70, 74, 78, 84, 86, 90, 94, 98, 102, and 106 will be described below.

As shown in FIG. 7, in the surface emitting semiconductor laser 70, as viewed from the stacking direction, the shape of an aperture 72A is elliptical and the shape of an opening 34A is circular. Therefore, the aperture 72A and the opening 34A have different shapes. In addition, a center 34C of the opening 34A is shifted from a center 72C of the aperture 72A. In addition, the surface emitting semiconductor laser 70 has a portion in which a distance L between an edge 34E of the opening 34A and an edge 72E of the aperture 72A continuously changes along the outer periphery of the aperture 72A as viewed from the stacking direction. In FIG. 7, a distance L2 indicates the minimum distance between the edge 34E of the opening 34A and the edge 72E of the aperture 72A. In addition, the distance L1 is longer than the distance L2. In the surface emitting semiconductor laser 70, in the portion having the similar configuration to the configuration of the surface emitting semiconductor laser 20 in the first exemplary embodiment, it is possible to obtain the similar operational effects to the operational effects in the first exemplary embodiment.

As shown in FIG. 8, in the surface emitting semiconductor laser 74, as viewed from the stacking direction, the shape of an aperture 76A is quadrangular and the shape of an opening 34A is circular. Therefore, the aperture 76A and the opening 34A have different shapes. In addition, a center 34C of the opening 34A is shifted from a center 76C of the aperture 76A. In addition, the surface emitting semiconductor laser 74 has a portion in which a distance L between an edge 34E of the opening 34A and an edge 76E of the aperture 76A continuously changes along the outer periphery of the aperture 76A as viewed from the stacking direction. In FIG. 8, a distance L2 indicates the minimum distance between the edge 34E of the opening 34A and the edge 72E of the aperture 72A. In addition, the distance L1 is longer than the distance L2. In the surface emitting semiconductor laser 74, in the portion having the similar configuration to the configuration of the surface emitting semiconductor laser 20 in the first exemplary embodiment, it is possible to obtain the similar operational effects to the operational effects in the first exemplary embodiment.

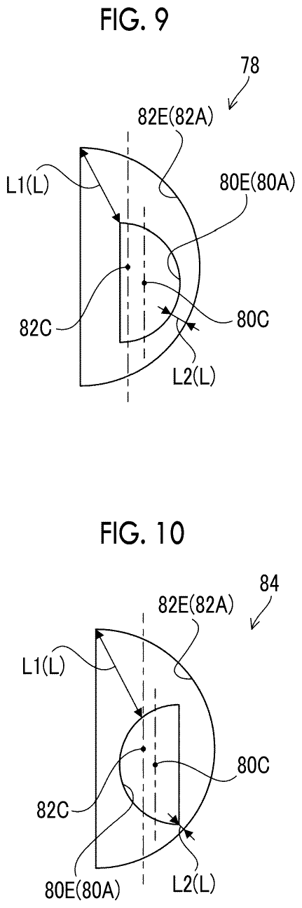

As shown in FIG. 9, in the surface emitting semiconductor laser 78, as viewed from the stacking direction, the shape of an aperture 80A is semicircular and the shape of an opening 82A is semicircular. Therefore, the aperture 80A and the opening 82A have the same shape. In addition, a center 82C of the opening 82A is shifted from a center 80C of the aperture 80A. In addition, the surface emitting semiconductor laser 78 has a portion in which a distance L between an edge 82E of the opening 82A and an edge 80E of the aperture 80A continuously changes along the outer periphery of the aperture 80A as viewed from the stacking direction. In FIG. 9, a distance L2 indicates the minimum distance between the edge 82E of the opening 82A and the edge 80E of the aperture 80A. In addition, the distance L1 is longer than the distance L2. In addition, in the surface emitting semiconductor laser 78, an arc portion of the aperture 80A and an arc portion of the opening 82A are directed in the same direction. In the surface emitting semiconductor laser 78, in the portion having the similar configuration to the configuration of the surface emitting semiconductor laser 20 in the first exemplary embodiment, it is possible to obtain the similar operational effects to the operational effects in the first exemplary embodiment. In addition, the surface emitting semiconductor laser 78 may have a configuration in which the center 80C of the aperture 80A and the center 82C of the opening 82A coincide with each other as in the surface emitting semiconductor laser 60 in the second exemplary embodiment.

As shown in FIG. 10, the surface emitting semiconductor laser 84 includes the aperture 80A and the opening 82A as in the surface emitting semiconductor laser 78, and the arc portion of the aperture 80A and the arc portion of the opening 82A are disposed in opposite directions. The other configurations of the surface emitting semiconductor laser 84 are similar to the other configurations of the surface emitting semiconductor laser 78. In the surface emitting semiconductor laser 84, in the portion having the similar configuration to the configuration of the surface emitting semiconductor laser 20 in the first exemplary embodiment, it is possible to obtain the similar operational effects to the operational effects in the first exemplary embodiment. In addition, the surface emitting semiconductor laser 84 may have a configuration in which the center 80C of the aperture 80A and the center 82C of the opening 82A coincide with each other as in the surface emitting semiconductor laser 60 in the second exemplary embodiment.

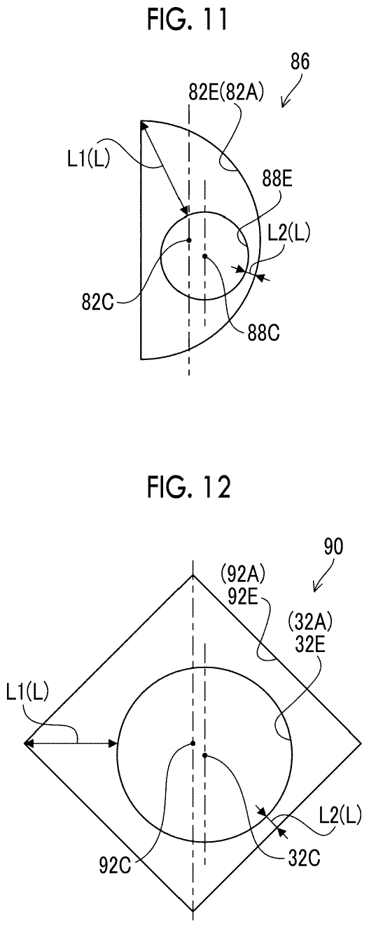

As shown in FIG. 11, in the surface emitting semiconductor laser 86, as viewed from the stacking direction, the shape of an aperture 88A is quadrangular and the shape of an opening 82A is semicircular. Therefore, the aperture 88A and the opening 82A have different shapes. In addition, a center 82C of the opening 82A is shifted from a center 88C of the aperture 88A. In addition, the surface emitting semiconductor laser 86 has a portion in which a distance L between an edge 82E of the opening 82A and an edge 88E of the aperture 88A continuously changes along the outer periphery of the aperture 88A as viewed from the stacking direction. In FIG. 11, a distance L2 indicates the minimum distance between the edge 82E of the opening 82A and the edge 88E of the aperture 88A. In addition, the distance L1 is longer than the distance L2. In the surface emitting semiconductor laser 86, in the portion having the similar configuration to the configuration of the surface emitting semiconductor laser 20 in the first exemplary embodiment, it is possible to obtain the similar operational effects to the operational effects in the first exemplary embodiment. In addition, the surface emitting semiconductor laser 86 may have a configuration in which the center 88C of the aperture 88A and the center 82C of the opening 82A coincide with each other as in the surface emitting semiconductor laser 60 in the second exemplary embodiment.

As shown in FIG. 12, in the surface emitting semiconductor laser 90, as viewed from the stacking direction, the shape of an aperture 32A is circular and the shape of an opening 92A is quadrangular. Therefore, the aperture 32A and the opening 92A have different shapes. In addition, a center 92C of the opening 92A is shifted from a center 32C of the aperture 32A. In addition, the surface emitting semiconductor laser 90 has a portion in which a distance L between an edge 92E of the opening 92A and an edge 32E of the aperture 32A continuously changes along the outer periphery of the aperture 32A as viewed from the stacking direction. In FIG. 12, a distance L2 indicates the minimum distance between the edge 92E of the opening 92A and the edge 32E of the aperture 32A. In addition, the distance L1 is longer than the distance L2. In the surface emitting semiconductor laser 90, in the portion having the similar configuration to the configuration of the surface emitting semiconductor laser 20 in the first exemplary embodiment, it is possible to obtain the similar operational effects to the operational effects in the first exemplary embodiment.

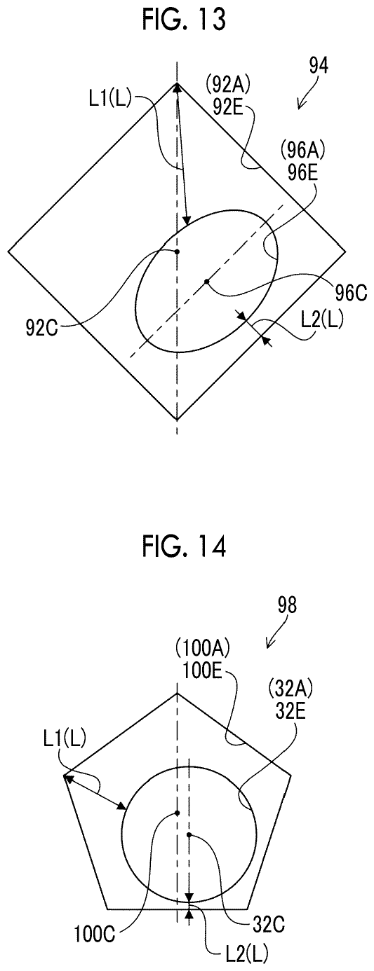

As shown in FIG. 13, in the surface emitting semiconductor laser 94, as viewed from the stacking direction, the shape of an aperture 96A is elliptical and the shape of an opening 92A is quadrangular. Therefore, the aperture 96A and the opening 92A have different shapes. In addition, a center 92C of the opening 92A is shifted from a center 96C of the aperture 96A. In addition, the surface emitting semiconductor laser 94 has a portion in which a distance L between an edge 92E of the opening 92A and an edge 96E of the aperture 96A continuously changes along the outer periphery of the aperture 96A as viewed from the stacking direction. In FIG. 13, a distance L2 indicates the minimum distance between the edge 92E of the opening 92A and the edge 96E of the aperture 96A. In addition, the distance L1 is longer than the distance L2. In the surface emitting semiconductor laser 94, in the portion having the similar configuration to the configuration of the surface emitting semiconductor laser 20 in the first exemplary embodiment, it is possible to obtain the similar operational effects to the operational effects in the first exemplary embodiment.

As shown in FIG. 14, in the surface emitting semiconductor laser 98, as viewed from the stacking direction, the shape of an aperture 32A is circular and the shape of an opening 100A is polygonal (pentagonal as an example). Therefore, the aperture 32A and the opening 100A have different shapes. In addition, a center 100C of the opening 100A is shifted from a center 32C of the aperture 32A. In addition, the surface emitting semiconductor laser 98 has a portion in which a distance L between an edge 100E of the opening 100A and an edge 32E of the aperture 32A continuously changes along the outer periphery of the aperture 32A as viewed from the stacking direction. In FIG. 14, a distance L2 indicates the minimum distance between the edge 100E of the opening 100A and the edge 32E of the aperture 32A. In addition, the distance L1 is longer than the distance L2. In the surface emitting semiconductor laser 98, in the portion having the similar configuration to the configuration of the surface emitting semiconductor laser 20 in the first exemplary embodiment, it is possible to obtain the similar operational effects to the operational effects in the first exemplary embodiment.

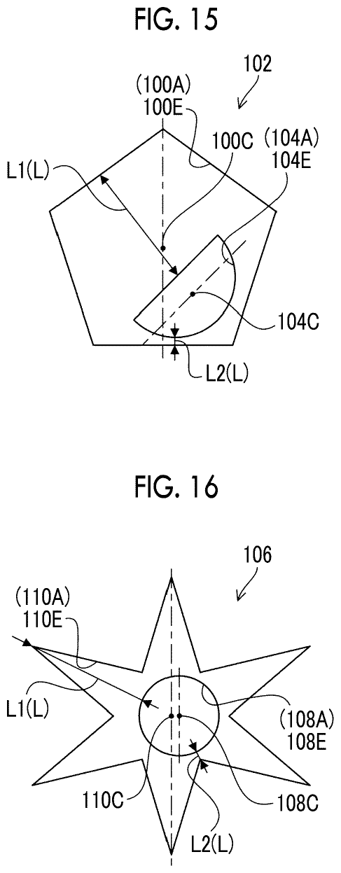

As shown in FIG. 15, in the surface emitting semiconductor laser 102, as viewed from the stacking direction, the shape of an aperture 104A is semicircular and the shape of an opening 100A is polygonal (pentagonal as an example). Therefore, the aperture 104A and the opening 100A have different shapes. In addition, a center 100C of the opening 100A is shifted from a center 104C of the aperture 104A. In addition, the surface emitting semiconductor laser 102 has a portion in which a distance L between an edge 100E of the opening 100A and an edge 104E of the aperture 104A continuously changes along the outer periphery of the aperture 104A as viewed from the stacking direction. In FIG. 15, a distance L2 indicates the minimum distance between the edge 100E of the opening 100A and the edge 104E of the aperture 104A. In addition, the distance L1 is longer than the distance L2. In the surface emitting semiconductor laser 102, in the portion having the similar configuration to the configuration of the surface emitting semiconductor laser 20 in the first exemplary embodiment, it is possible to obtain the similar operational effects to the operational effects in the first exemplary embodiment. In addition, the surface emitting semiconductor laser 102 may have a configuration in which the center 104C of the aperture 104A and the center 100C of the opening 100A coincide with each other as in the surface emitting semiconductor laser 60 in the second exemplary embodiment.

As shown in FIG. 16, in the surface emitting semiconductor laser 106, as viewed from the stacking direction, the shape of an aperture 108A is circular and the shape of an opening 110A is polygonal (star-like as an example). Therefore, the aperture 108A and the opening 110A have different shapes. In addition, a center 110C of the opening 110A is shifted from a center 108C of the aperture 108A. In addition, the surface emitting semiconductor laser 106 has a portion in which a distance L between an edge 110E of the opening 110A and an edge 108E of the aperture 108A continuously changes along the outer periphery of the aperture 108A as viewed from the stacking direction. In FIG. 16, a distance L2 indicates the minimum distance between the edge 110E of the opening 110A and the edge 108E of the aperture 108A. In addition, the distance L1 is longer than the distance L2. In the surface emitting semiconductor laser 106, in the portion having the similar configuration to the configuration of the surface emitting semiconductor laser 20 in the first exemplary embodiment, it is possible to obtain the similar operational effects to the operational effects in the first exemplary embodiment. In addition, the surface emitting semiconductor laser 106 may have a configuration in which the center 108C of the aperture 108A and the center 110C of the opening 110A coincide with each other as in the surface emitting semiconductor laser 60 in the second exemplary embodiment.

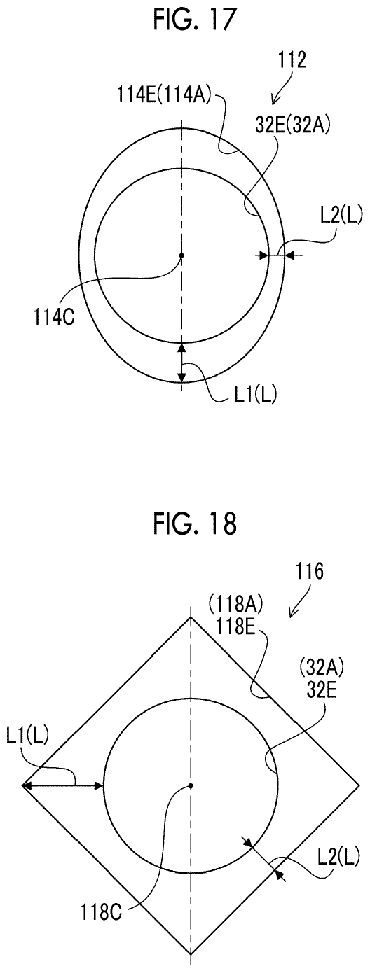

In the surface emitting semiconductor laser 60 in the second exemplary embodiment, as viewed from the stacking direction, the shape of the aperture 62A is elliptical and the shape of the opening 34A is circular, but the present disclosure is not limited to this configuration. For example, surface emitting semiconductor lasers 112, 116, 120, 124, 128, 132, and 136 shown in FIGS. 17 to 23 may be used. The surface emitting semiconductor lasers 112, 116, 120, 124, 128, 132, and 136 will be described below.

As shown in FIG. 17, in the surface emitting semiconductor laser 112, as viewed from the stacking direction, the shape of an aperture 32A is circular and the shape of an opening 114A is elliptical. Therefore, the aperture 32A and the opening 114A have different shapes. In addition, a center 32C of the aperture 32A and a center 114C of the opening 114A coincide with each other. In addition, the surface emitting semiconductor laser 112 has a portion in which a distance L between an edge 114E of the opening 114A and an edge 32E of the aperture 32A continuously changes along the outer periphery of the aperture 32A as viewed from the stacking direction. In FIG. 17, a distance L2 indicates the minimum distance between the edge 114E of the opening 114A and the edge 32E of the aperture 32A. In addition, the distance L1 is longer than the distance L2. In the surface emitting semiconductor laser 112, in the portion having the similar configuration to the configuration of the surface emitting semiconductor laser 60 in the second exemplary embodiment, it is possible to obtain the similar operational effects to the operational effects in the second exemplary embodiment.

As shown in FIG. 18, in the surface emitting semiconductor laser 116, as viewed from the stacking direction, the shape of an aperture 32A is circular and the shape of an opening 118A is quadrangular. Therefore, the aperture 32A and the opening 118A have different shapes. In addition, a center 32C of the aperture 32A and a center 118C of the opening 118A coincide with each other. In addition, the surface emitting semiconductor laser 116 has a portion in which a distance L between an edge 118E of the opening 118A and an edge 32E of the aperture 32A continuously changes along the outer periphery of the aperture 32A as viewed from the stacking direction. In FIG. 18, a distance L2 indicates the minimum distance between the edge 118E of the opening 118A and the edge 32E of the aperture 32A. In addition, the distance L1 is longer than the distance L2. In the surface emitting semiconductor laser 116, in the portion having the similar configuration to the configuration of the surface emitting semiconductor laser 60 in the second exemplary embodiment, it is possible to obtain the similar operational effects to the operational effects in the second exemplary embodiment.

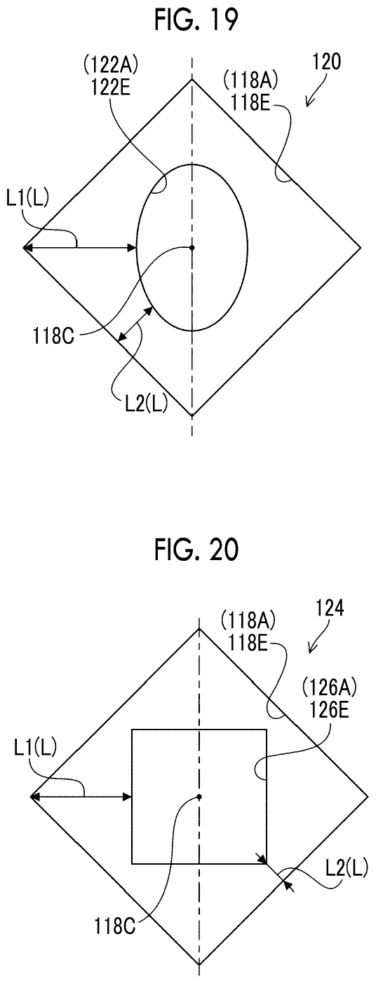

The shape of an aperture 122A may be elliptical as in the surface emitting semiconductor laser 120 shown in FIG. 19. Also in the surface emitting semiconductor laser 120, in a portion having the similar configuration to the configuration of the surface emitting semiconductor laser 60 in the second exemplary embodiment, it is possible to obtain the similar operational effects to the operational effects in the second exemplary embodiment. In FIG. 19, the reference numeral 122E indicates an edge of the aperture 122A.

In addition, as in the surface emitting semiconductor laser 124 shown in FIG. 20, the shape of an aperture 126A may be quadrangular. Also in the surface emitting semiconductor laser 124, in a portion having the similar configuration to the configuration of the surface emitting semiconductor laser 60 in the second exemplary embodiment, it is possible to obtain the similar operational effects to the operational effects in the second exemplary embodiment. In FIG. 20, the reference numeral 126E indicates an edge of the aperture 126A.

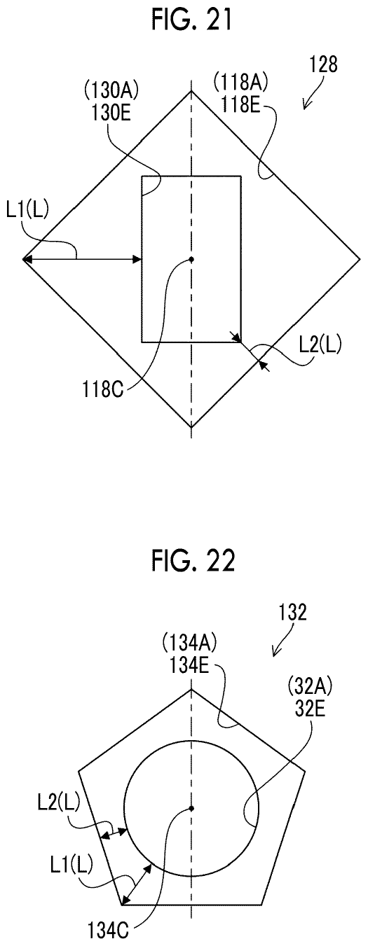

In addition, as in the surface emitting semiconductor laser 128 shown in FIG. 21, the shape of an aperture 130A may be rectangular. Also in the surface emitting semiconductor laser 128, in a portion having the similar configuration to the configuration of the surface emitting semiconductor laser 60 in the second exemplary embodiment, it is possible to obtain the similar operational effects to the operational effects in the second exemplary embodiment. In FIG. 21, the reference numeral 130E indicates an edge of the aperture 130A.

As shown in FIG. 22, in the surface emitting semiconductor laser 132, as viewed from the stacking direction, the shape of an aperture 32A is circular and the shape of an opening 134A is polygonal (pentagonal as an example). Therefore, the aperture 32A and the opening 134A have different shapes. In addition, a center 32C of the aperture 32A and a center 134C of the opening 134A coincide with each other. In addition, the surface emitting semiconductor laser 132 has a portion in which a distance L between an edge 134E of the opening 134A and an edge 32E of the aperture 32A continuously changes along the outer periphery of the aperture 32A as viewed from the stacking direction. In FIG. 22, a distance L2 indicates the minimum distance between the edge 134E of the opening 134A and the edge 32E of the aperture 32A. In addition, the distance L1 is longer than the distance L2. In the surface emitting semiconductor laser 132, in the portion having the similar configuration to the configuration of the surface emitting semiconductor laser 60 in the second exemplary embodiment, it is possible to obtain the similar operational effects to the operational effects in the second exemplary embodiment.

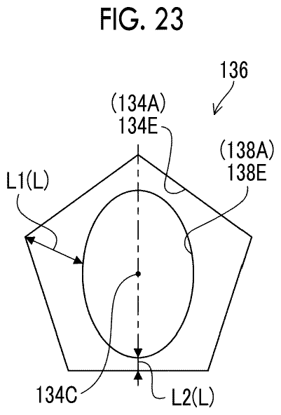

In addition, as in the surface emitting semiconductor laser 136 shown in FIG. 23, the shape of an aperture 138A may be elliptical. Also in the surface emitting semiconductor laser 136, in a portion having the similar configuration to the configuration of the surface emitting semiconductor laser 60 in the second exemplary embodiment, it is possible to obtain the similar operational effects to the operational effects in the second exemplary embodiment. In FIG. 23, the reference numeral 138E indicates an edge of the aperture 138A.

Among the examples included in the techniques of the present disclosure described above, all the examples shown in FIGS. 3, 6, 7, 8, 9, 10, 11, 12, 13, 14, 15, 16, 17, 18, 19, 20, 21, 22, and 23 are examples in which the portion in which the distance L between the edge of the opening and the edge of the aperture continuously changes along the outer periphery of the aperture is provided as viewed from the stacking direction. In addition, all the examples shown in FIGS. 8, 9, 10, 11, 12, 13, 14, 15, 16, 18, 19, 20, 21, 22, and 23 are examples in which, as viewed from the stacking direction, the portion in which the distance L between the edge of the opening and the edge of the aperture continuously changes along the outer periphery of the aperture and the portion in which the distance L intermittently changes along the outer periphery of the aperture are provided. In addition, all the examples shown in FIGS. 3, 6, 7, and 17 are examples in which the distance between the edge of the opening and the edge of the aperture continuously changes over the entire circumference of the aperture as viewed from the stacking direction.

In addition, in the exemplary embodiments described above, the recess portion 50 is provided in the second semiconductor multilayer film reflective mirror 30, but the recess portion 50 may not be provided.

The exemplary embodiments of the surface emitting semiconductor laser 20 have been described above. The exemplary embodiment may be in the form of an optical transmission apparatus including the surface emitting semiconductor laser 20. The optical transmission apparatus includes an optical transmission unit (not shown) that transmits light output from the surface emitting semiconductor laser 20. In such an optical transmission apparatus, even in a case where the use environment is changed, it is possible to perform stable optical transmission as compared to a case of using the surface emitting semiconductor laser having a configuration in which the opening 34A and the aperture 32A have the same shape and the centers 34C and 32C coincide with each other as viewed from the stacking direction. As a result, it is possible to increase an optical transmission speed. In addition, in the above exemplary embodiments, the surface emitting semiconductor laser based on GaAs using the semi-insulating GaAs substrate has been described as an example. The present disclosure is not limited to this and may be in the form of using a substrate based on gallium nitride (GaN) or a substrate based on indium phosphide (InP). In a case where the material of the substrate is changed, it is necessary to appropriately set the material and a confinement method of the substrate material. For example, in the case of a GaN substrate, a pair of aluminum gallium nitride (AlGaN) and GaN may be used for a lower DBR which will be described later, a pair of an indium gallium nitride (InGaN) quantum well layer and a GaN barrier layer may be used for an active layer, and a dielectric DBR may be used for an upper DBR.

In addition, for example, in the case of an InP substrate, a pair of InGaAsP having a different composition may be used for a lower DBR, an InGaAsP quantum well layer and a barrier layer having different compositions may be used for an active layer, and a dielectric DBR may be used for an upper DBR.

In addition, in a case where a GaN substrate and an InP substrate are used, it is not possible to use a material capable of selective oxidation and to perform oxidation confinement. Thus, for example, current confinement by an embedded tunnel junction may be used.

In addition, while the form of forming the contact layer of the n-type on the substrate has been described as an example in the above exemplary embodiments, the present disclosure is not limited to this and may be in the form of forming a contact layer of the p-type on the substrate. In this case, the n-type and the p-type may be replaced with each other in reverse in the above description.

The present disclosure is not limited to the above description, and can be variously modified and implemented in a range without departing from the gist of the present invention.

Regarding the above exemplary embodiments, the following supplementary notes will be further disclosed.

(((1)))

A surface emitting semiconductor laser comprising:
a substrate;
a first semiconductor multilayer film reflective mirror stacked on the substrate;
an active layer stacked on the first semiconductor multilayer film reflective mirror;
a second semiconductor multilayer film reflective mirror that includes a current confinement layer and is stacked on the active layer;
a dielectric multilayer film reflective mirror stacked on the second semiconductor multilayer film reflective mirror; and
a metal layer that is disposed between the second semiconductor multilayer film reflective mirror and the dielectric multilayer film reflective mirror, has an opening in which an aperture representing a portion that is not subjected to oxidation confinement in the current confinement layer is disposed inside as viewed from a stacking direction, and has a center of the opening at a position shifted from a center of the aperture.
   (((2)))

The surface emitting semiconductor laser according to (((1))),
wherein, as viewed from the stacking direction, a portion in which a distance between an edge of the opening and an edge of the aperture continuously changes along an outer periphery of the aperture is provided.
   (((3)))

The surface emitting semiconductor laser according to (((2))),
wherein, as viewed from the stacking direction, at least one edge of the opening or the aperture is curved in an arc shape.
   (((4)))

The surface emitting semiconductor laser according to (((2))),
wherein, as viewed from the stacking direction, the distance between the edge of the opening and the edge of the aperture continuously changes over an entire circumference of the aperture.
   (((5)))

The surface emitting semiconductor laser according to (((4))),
wherein the aperture has a circular or elliptical shape, and
the opening has a circular or elliptical shape.
   (((6)))

The surface emitting semiconductor laser according to (((5))),
wherein, as viewed from the stacking direction, the shape of the opening is the same as the shape of the aperture.
   (((7)))

The surface emitting semiconductor laser according to (((1))),
wherein a recess portion is formed in an uppermost layer of the second semiconductor multilayer film reflective mirror, and
as viewed from the stacking direction, the recess portion is disposed inside the aperture and a center of the recess portion is located at a position shifted from the center of the aperture.
   (((8)))

The surface emitting semiconductor laser according to (((7))),
wherein the aperture has a circular or elliptical shape, and
the recess portion has a circular or elliptical shape.
   (((9)))

The surface emitting semiconductor laser according to (((8))),
wherein, as viewed from the stacking direction, the shape of the recess portion is the same as the shape of the aperture.
   (((10)))

A surface emitting semiconductor laser comprising:
a substrate;
a first semiconductor multilayer film reflective mirror stacked on the substrate;
an active layer stacked on the first semiconductor multilayer film reflective mirror;
a second semiconductor multilayer film reflective mirror that includes a current confinement layer and is stacked on the active layer;
a dielectric multilayer film reflective mirror stacked on the second semiconductor multilayer film reflective mirror; and
a metal layer that is disposed between the second semiconductor multilayer film reflective mirror and the dielectric multilayer film reflective mirror, has an opening in which an aperture representing a portion that is not subjected to oxidation confinement in the current confinement layer is disposed inside as viewed from a stacking direction, and the metal layer in which a plurality of external resonators having different resonance frequencies are formed between an edge of the opening and an edge of the aperture.
   (((11)))

An optical transmission apparatus comprising:
the surface emitting semiconductor laser according to (((1))) or ((10))); and
an optical transmission unit that transmits light output from the surface emitting semiconductor laser.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A surface emitting semiconductor laser comprising:
a substrate;
a first semiconductor multilayer film reflective mirror stacked on the substrate;
an active layer stacked on the first semiconductor multilayer film reflective mirror;
a second semiconductor multilayer film reflective mirror that includes a current confinement layer and is stacked on the active layer;
a dielectric multilayer film reflective mirror stacked on the second semiconductor multilayer film reflective mirror; and
a metal layer that is disposed between the second semiconductor multilayer film reflective mirror and the dielectric multilayer film reflective mirror, has an opening in which an aperture representing a portion that is not subjected to oxidation confinement in the current confinement layer is disposed inside as viewed from a stacking direction, and has a center of the opening at a position shifted from a center of the aperture.

2. The surface emitting semiconductor laser according to claim 1,
wherein, as viewed from the stacking direction, a portion in which a distance between an edge of the opening and an edge of the aperture continuously changes along an outer periphery of the aperture is provided.

3. The surface emitting semiconductor laser according to claim 2,
wherein, as viewed from the stacking direction, at least one edge of the opening or the aperture is curved in an arc shape.

4. The surface emitting semiconductor laser according to claim 2,
wherein, as viewed from the stacking direction, the distance between the edge of the opening and the edge of the aperture continuously changes over an entire circumference of the aperture.

5. The surface emitting semiconductor laser according to claim 4,
wherein the aperture has a circular or elliptical shape, and
the opening has a circular or elliptical shape.

6. The surface emitting semiconductor laser according to claim 5,
wherein, as viewed from the stacking direction, the shape of the opening is the same as the shape of the aperture.

7. The surface emitting semiconductor laser according to claim 1,
wherein a recess portion is formed in an uppermost layer of the second semiconductor multilayer film reflective mirror, and
as viewed from the stacking direction, the recess portion is disposed inside the aperture and a center of the recess portion is located at a position shifted from the center of the aperture.

8. The surface emitting semiconductor laser according to claim 7,
wherein the aperture has a circular or elliptical shape, and
the recess portion has a circular or elliptical shape.

9. The surface emitting semiconductor laser according to claim 8,
wherein, as viewed from the stacking direction, the shape of the recess portion is the same as the shape of the aperture.

10. A surface emitting semiconductor laser comprising:
a substrate;
a first semiconductor multilayer film reflective mirror stacked on the substrate;
an active layer stacked on the first semiconductor multilayer film reflective mirror;
a second semiconductor multilayer film reflective mirror that includes a current confinement layer and is stacked on the active layer;
a dielectric multilayer film reflective mirror stacked on the second semiconductor multilayer film reflective mirror; and
a metal layer that is disposed between the second semiconductor multilayer film reflective mirror and the dielectric multilayer film reflective mirror, has an opening in which an aperture representing a portion that is not subjected to oxidation confinement in the current confinement layer is disposed inside as viewed from a stacking direction, and the metal layer in which a plurality of external resonators having different resonance frequencies are formed between an edge of the opening and an edge of the aperture.

11. An optical transmission apparatus comprising:
the surface emitting semiconductor laser according to claim 1; and
an optical transmission unit that transmits light output from the surface emitting semiconductor laser.

12. An optical transmission apparatus comprising:
the surface emitting semiconductor laser according to claim 10; and
an optical transmission unit that transmits light output from the surface emitting semiconductor laser.
